(19) United States
(12) Patent Application Publication
(10) Pub. No.: US 2026/0173337 A1
(43) Pub. Date: Jun. 18, 2026

(54) PROTECTIVE TEXTILE COATING AND PROTECTIVE FABRIC LINER SYSTEM

(71) Applicant: Bondcote Performance Textiles, Inc., Pulaski, VA (US)

(72) Inventors: Joe Daniel, High Point, NC (US); Michael Hoadley, Pulaski, VA (US)

(21) Appl. No.: 19/387,332

(22) Filed: Nov. 12, 2025

Related U.S. Application Data
(60) Provisional application No. 63/719,533, filed on Nov. 12, 2024.
(60) Provisional application No. 63/741,695, filed on Jan. 3, 2025.

(51) Int. Cl. H05K 9/00; B32B 5/02; B32B 7/09; B32B 7/12; B32B 27/12; B32B 27/30; B32B 27/36

(52) U.S. Cl. CPC H05K 9/009; B32B 5/024; B32B 5/028; B32B 7/09; B32B 7/12; B32B 27/12; B32B 27/304; B32B 27/36; B32B 2250/05; B32B 2262/0276; B32B 2262/128; B32B 2307/212; B32B 2307/3065; B32B 2307/714; B32B 2307/718; B32B 2307/7242; B32B 2307/7265

(57) ABSTRACT

A protective textile coating system includes an inner protective layer, a structural layer, a first adhesive, an electro-magnetic interference (EMI) resistant or EMI blocking layer, and a second adhesive. The first adhesive can be selected, adapted or otherwise configured to bond the protective layer and the structural layer. The second adhesive can be selected, adapted or otherwise configured to chemically react or interact with the EMI resistant layer in order to form a bond between the EMI resistant layer and the structural layer. A protective coated textile product can also be provided, by applying the protective coating to a textile or fabric layer.

### CROSS-REFERENCE TO RELATED APPLICATIONS

This application claims priority to U.S. Provisional Application No. 63/719,533, filed Nov. 12, 2024, “Protective Textile Coating and Protective Fabric Liner System,” and U.S. Provisional Application No. 63/741,695, filed Jan. 3, 2025, “EMI Protective Textile Coating and EMI Protective Fabric Liner System,” each of which is incorporated by reference herein, in the entirety and for all purposes.

### BACKGROUND

Textiles are used in a wide variety of applications. For example, textiles can be used to form structures, such as those for rapid deployment. Structures can include vehicle hangers, storage, camp solutions, and semi-permanent structures. Polytetrafluoroethylene (PTFE) has long been used due to its chemical resistance and versatility, but poses environmental and health concerns.

### SUMMARY

A textile coating can be provided with one or more of an electro-magnetic interference (EMI) resistant layer, a structural layer, a permeability resistant layer, and first and second adhesives. The first adhesive can be selected, formulated, specially adapted or otherwise configured to bond the electro-magnetic interference (EMI) resistant layer to the structural layer, for example via a chemical reaction forming a chemical bond or chemically reactive bond. The second adhesive can be selected, formulated, specially adapted or otherwise configured to react with the permeability resistant layer in order to form a bond between the permeability resistant layer and the structural layer, for example via a chemical reaction forming a chemical bond or chemically reactive bond.

Depending on application, the protective layer can include or comprise polyvinyl chloride, a polyvinyl film, or other polyvinyl chloride material. The EMI resistant layer can include or comprise woven material including metalized fibers. The metalized fibers can include at least one of copper, nickel, tin, zinc, silver, or a combination thereof. The structural layer can include or comprise a polyester film, polyester scrim or other polyester material, and the permeability resistant layer can include or comprise polyvinyl fluoride, a polyvinyl fluoride film or other polyvinyl fluoride material.

The protective layer can also be deposited or otherwise disposed on a layer of textile or fabric. A further adhesive can be provided to bond the structural layer to textile or fabric; e.g., similar to the first or second adhesive, or using a different adhesive material.

In various examples and embodiments, the first adhesive can be selected from or comprise one or more suitable chemical adhesives, or the first adhesive may include or comprise one or more such chemical adhesives. The textile coating can be flame or fire resistant, or resistant to corrosion, or any combination thereof. The textile coating can also be resistant to transmission of selected permeable gases or fluids, or both, for example gaseous or fluid environmental contaminants or hazards. The textile coating can be resistant to EMI.

Depending on application, the textile coating can have a total weight of about 15.3 ounces per square yard, or about 505-515 grams per square meter. In some applications, the textile coating can a total weight between about 14.5 and about 16.3 ounces per square yard, or between about 500 and about 550 grams per square meter.

A coated textile fabric can also be provided, including one or more of a textile or fabric layer, a first protective layer, a permeability resistant layer, a first adhesive, a structural layer, a second adhesive, an EMI resistant layer, and a third adhesive. The first adhesive can be selected, formulated, specially adapted or otherwise configured to bond the protective layer and the permeability resistant layer. The second adhesive can be selected, formulated, specially adapted or otherwise configured to react with the permeability resistant layer to form a bond between the permeability resistant layer and the structural layer, via a chemical reaction forming a chemical bond or chemically reactive bond. The third adhesive can be selected, formulated, specially adapted, or otherwise configured to react with the EMI resistant layer to form a bond between the EMI resistant layer and the structural layer, via a chemical reaction forming a chemical bond or chemically reactive bond.

Depending on application, the coated textile fabric can also include one or more of a second protective layer and a fourth adhesive. The third adhesive can be selected, formulated, adapted or otherwise configured to bond the second protective layer and the EMI resistant layer.

The EMI resistant layer can include or comprise a woven material including metalized fibers. The metalized fibers can include at least one of copper, nickel, tin, zinc, silver, or a combination thereof. The first and second protective layers can each include or comprise polyvinyl chloride, a polyvinyl chloride material, or a polyvinyl chloride film. The structural layer can include or comprise a polyester material, a polyester film, or a polyester scrim. The permeability resistant layer can include or comprise polyvinyl fluoride, a polyvinyl fluoride material or a polyvinyl fluoride film.

The coated textile can be resistant to corrosion, flame retardant, or both. The coated textile can also be resistant to transmission of selected permeable gases or fluids, or both, for example gaseous or fluid environmental contaminants or hazards. The coated textile can also be resistant to EMI.

Depending on application, the coated textile can have a total weight of about 20.1 ounces per square yard, or about 675-685 grams per square meter. In some applications, the coated textile can a total weight between about 17 and about 23 ounces per square yard, or between about 600 and about 800 grams per square meter.

A method of creating a coated textile can include applying one or more of a protective layer, a first adhesive, a structural layer, a second adhesive, and an EMI resistant layer to a textile. The first adhesive can be selected, formulated, specially adapted or otherwise configured to bond the protective layer and a structural layer. The second adhesive can be selected, formulated, specially adapted or otherwise configured to react with the EMI resistant layer in order to form a bond between the EMI resistant layer and the structural layer, for example via a chemical reaction forming a chemical bond or chemically reactive bond.

Depending on the application, the method can include applying a third adhesive and a second protective layer. The third adhesive can be selected, formulated, specially adapted or otherwise configured to bond the second protective layer and the EMI resistant layer. Depending on the application, the method can include applying a permeability resistant layer between the protective layer and the structural layer.

Depending on application, the protective layer can include or comprise polyvinyl chloride, a polyvinyl film, or other polyvinyl chloride material. The EMI resistant layer can include a woven fabric with metalized fibers. The structural layer can include or comprise a polyester film, polyester scrim or other polyester material, and the permeability resistant layer can include or comprise polyvinyl fluoride, a polyvinyl fluoride film or other polyvinyl fluoride material.

In various examples and embodiments, the first adhesive, second adhesive, and/or third adhesive can be selected from or comprise one or more suitable chemical adhesives, or the first adhesive, second adhesive, and/or third adhesive may include or comprise one or more such chemical adhesives. The textile coating can be flame and fire resistant, resistant to corrosion, or both. The textile coating can also be resistant to transmission of selected permeable gases or fluids, or both, for example gaseous or fluid environmental contaminants or hazards. The textile coating can also be resistant to EMI.

Depending on application, the textile coating can have a total weight of about 15.3 ounces per square yard, or about 505-515 grams per square meter. In some applications, the textile coating can a total weight of about 20.1 ounces per square yard, or between about 675 and about 685 grams per square meter.

### BRIEF DESCRIPTION OF THE DRAWINGS

FIG. 1 is a schematic diagram of a structure with a protective textile coating.

FIG. 2 is a schematic diagram of a structure with a protective fabric liner system.

FIG. 3 is a schematic diagram of an alternate layer configuration for the protective fabric liner system.

FIG. 4 is a front elevation view illustrating a structure with the protective textile coating and a protective fabric liner system.

FIG. 5 is a block diagram of a method for applying a protective coating to a layer of textile or fabric.

FIG. 6 is a schematic diagram of a structure with a protective fabric liner system.

FIG. 7 is a schematic diagram of a structure with a protective textile coating.

FIG. 8 is a block diagram of a method for applying a protective coating to a layer of textile or fabric.

### DETAILED DESCRIPTION

Textiles for portable and permanent structures, including structures for military use, must be able to withstand extreme conditions to protect the people and equipment within the structures. For example, structures made of textiles and fabric materials may also need to protect occupants from chemical and biological warfare agents, such as noxious gases and biological agents, and other gaseous or fluid environmental contaminants and hazards. As another example, structures made of textiles and fabric materials may also need to shield from electro-magnetic interference, to protect against electronic surveillance.

Some chemical or biological warfare gases and environmental contaminants are corrosive or have high permeability. Some, if not most, chemical and biological warfare gases can permeate and be transmitted through standard textile materials. Examples of such chemical and biological warfare agents include sarin gas and mustard gas, and fluid-borne biological agents. The textile should also be able to protect occupants from weather hazards and other environmental risks, including ultraviolet rays, wind, rain, extreme temperatures, snow loads, etc.

This disclosure relates to a textile coating, a coated textile product, or a protective fabric liner system capable of withstanding weather extremes, as well as chemical and biological warfare agents and/or electro-magnetic interference. The textile coating can also be adapted to protect the underlying textile or fabric material from corrosion. The textile coating or coated textile product can protect occupants from permeable gases and fluids.

The textile coating or coated textile can also protect against electronic surveillance. The coated textile or fabric product can, for example be used for manufacturing portable or permanent shelters and structures. By integrating chemical, biological, and electromagnetic protection into a single material, the textile coating, a coated textile product, or a protective fabric liner system can provide a versatile, high-performance solution tailored to the evolving needs of military and defense applications.

For example, the coated textile or fabric product can include a Polytetrafluoroethylene (PTFE) or polyvinylflouride (PVF) layer, which have chemical resistance properties. PVF can be completely PFAS free, to align with evolving environmental and health standards. To achieve strong inter-layer bonding, the PTFE or PVF layer can be chemically etched to enable adhesion and facilitate cohesive bonding of PVC, PTFE or PVF, and polyester layers. The PTFE or PVF layer can be sandwiched between PVC and polyester cloth using adhesives or coatings to encapsulate the PTFE or PVF.

The adhesive or coatings can provide a robust bond between PVF and PVC layers and enhance layer cohesion. The adhesive or coating can support a wider range of applications for the textile coating or coated textile product. In an example, the PVF can have a production width similar to a PVC layer, which can allow the textile coating or coated textile product to be manufactured in wider rolls. By providing wider rolls, the textile coating or coated textile product can require less seems, and therefore have a decreased vulnerability compared to other protective fabrics. The fabrication process of the textile coating or coated textile product can be simplified, thus minimizing the likelihood of breaches and enhancing overall durability.

The textile coating or coated textile product can include multiple layers, with each layer carefully selected, formulated, specially adapted or otherwise configured to provide a range of these different protections, as well as sufficient structural stability, product integrity, and longevity. The multiple layers of the textile coating or coated textile product can provide the chemical and biological resilience in a versatile format. The textile coating or coated textile product can be suitable for welding, and therefore ideal for military applications.

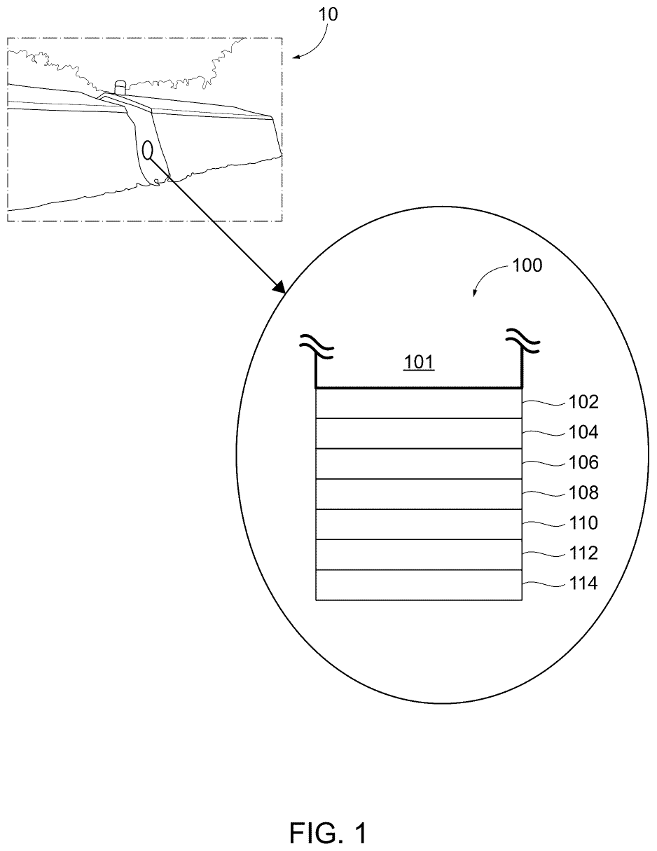

FIG. 1 is a schematic diagram of a structure 10 with a protective textile coating 100, as described herein. Referring to FIG. 1, a textile coating 100 can include multiple layers. For example, the textile coating 100 may include up to seven or more layers disposed on the inner side of a textile or fabric layer 101, in order to form a coated textile system. The coating layers can include a first layer 102, a second layer 104, a third layer 106, a fourth layer 108, a fifth layer 110, a sixth layer 112, and a seventh layer 114.

The first layer 102 can be a protective layer. In some applications, for example, the first layer (protective layer) 102 is formed of or includes polyvinyl chloride (PVC), or a PVC material or PVC film. Depending on formulation the first layer 102 can provide resistance to weather. The first layer 102 can also provide resistance to abrasion and tears. The first layer 102 can also be resistant to chemicals.

Depending on application, the first (protective) layer 102 may can be approximately 4-5 mm thick. The first layer 102 can be colored or pigmented to modulate absorption of solar energy (e.g., to increase reflectance and decrease heat capture, or to decrease reflectance and increase heat capture), or to provide camouflaging. For example, the first layer 102 may be provided with white, tan, green, brown, black, or other pigments, or a combination thereof. Depending on application, the first layer 102 can also have a weight of about 5 ounces per square yard, or about 165-175 grams per square meter (GSM), or in a range or about 50 to 350 GSM, or more or less.

The second layer 104 can be formed from or comprise an adhesive, for example a chemical adhesive. The adhesive in the second layer 104 can be selected, formulated, specially adapted or otherwise configured to bond with the first layer 102, for example via a chemical bonding process. The second layer (adhesive layer) 104 can also be configured to bond with the third layer 106; e.g., via a similar chemical process. The second layer 104 can include a resin, a plasticizer, an FR (flame retardant), and an adhesion promoter. The second layer 104 can also include a mildewcide. In an example, the second layer can include approximately 42% resin, approximately 36% plasticizer, approximately 13.5% FR, approximately 6.5% adhesion promoter, and approximately 2% mildewcide. In an example, the second layer 104 can have an approximate composition as shown in Table 1.

Depending on application, the second layer 104 can have a weight of about 0.75 ounces per square yard, or about 20 to about 30 GSM, or in a range of about 10 to 60 GSM, or more or less.

TABLE 1
Second layer 104 (approximate composition)

| | Percent |
|---|---|
| Component | (approximate) |
| DUP (diundecyl phthalate) | 35.7% |
| 5% 4-Isothazolin-3-one, 2-octyl | 1.9% |
| (in dioctyl terephthalate/DOTP) | |
| T75M (PVC Resin) | 37.8% |
| Vestolit 137 (PVC Resin) | 4.2% |
| Alumina Trihydrate | 5.3% |
| Antimony Trioxide | 8.4% |
| Toluene diisocyanate homopolymer | 6.7% |
| (in Benzyl Benzoate) | |

The third layer 106 can be configured to provide strength and structural stability to the textile coating 100. Depending on application, the third layer (or stability layer) 106 can be formed of or include a polyester material, a polyester film, a polyester scrim, or a Greige cloth. For example, the third layer 106 can be formed of a woven polyester fabric, or other woven fabric material. Depending on desired strength, density and other properties, the third layer 106 can have a thread count or fiber density of approximately 14×14 (1000 D×1000 D), or approximately 9×9 (500 D×500 D), for example in a weft inserted warp knit configuration. Depending on application, the third layer 106 can have a weight of about 3.6 ounces per square yard, or about 120 to about 125 GSM, or in a range of about 10-60 GSM, or more or less.

The fourth layer 108 can include or comprise an adhesive, for example a resin type adhesive. The adhesive in the fourth layer 108 can be selected or formulated to “attack” (react with) the material of the fifth layer 110, in order to create a bond. For example, the adhesive of the fourth layer 108 can be formulated to bond with the fifth layer 110 via a chemical reaction with the material of the fifth layer 110. The adhesive in the fourth layer 108 can also permeate, partially permeate, migrate, or partially migrate the material of the fifth layer 110 to create a chemical or chemically activated bond from the reaction with the adhesive.

The adhesive in fourth layer 108 can also bond with the material of the third (structural) layer 106. Typically, the adhesive in the fourth layer 108 can bond with the material of the third layer 106 via a chemical reaction. Depending on the selected type and concentration of adhesive material, the fourth layer 108 can have a weight of about 0.75 ounces per square yard, or about 20 to about 30 GSM, or in a range of about 10 to 60 GSM, or more or less.

The fifth layer 110 can be selected, formulated, specially adapted or otherwise configured to provide chemical resistance. In some applications, the fifth layer 110 can include or comprise polyvinyl fluoride (PVF), or a PVF material or PVF film. For example, the fifth (chemically resistant) layer 110 can be configured as a PVF film.

The material of the fifth layer 110 can be selected or formulated to prevent transmission of permeable chemical agents and biological warfare vectors. The material of the fifth layer 110 can also be selected to have a reduced or minimal impact on the environment, compared to other disfavored materials such as polytetrafluoroethylen (PTFE), and related compounds. Depending on application, the fifth layer 110 may have a weight of about 2 ounces per square yard, or about 65 to about 70 GSM, or in a range of about 30 to 150 GSM, or more or less.

The sixth layer 112 can include or comprise an additional adhesive material. The adhesive of the sixth layer 112 may be similar to that of the second layer 104 or the fourth layer 108. For example, the sixth layer 112 can comprise or include a chemical adhesive that bonds with the surrounding (adjacent) layers through a chemical reaction, migration, and/or permeation of the material in the adjacent layers. The sixth layer 112 can include a resin, a plasticizer, an FR, and an adhesion promoter. The sixth layer 112 can also include a mildewcide. In an example, the sixth layer 112 can include approximately 42% resin, approximately 36% plasticizer, approximately 13.5% FR, approximately 6.5% adhesion promoter, and approximately 2% mildewcide. In an example, the sixth layer 112 can have an approximate composition as shown in Table 2.

Depending on application, the sixth layer 112 can have a weight of about 0.75 ounces per square yard, or about 20 to about 30 GSM, or in a range of about 10 to 60 GSM, or more or less.

TABLE 2
Sixth layer 112 (approximate composition)

| | Percent |
|---|---|
| Component | (approximate) |
| DUP (diundecyl phthalate) | 34.6% |
| 5% 4-Isothazolin-3-one, 2-octyl | 1.8% |
| (in dioctyl terephthalate/DOTP) | |
| T75M (PVC Resin) | 36.7% |
| Vestolit 137 (PVC Resin) | 4.1% |
| Alumina Trihydrate | 5.1% |
| Antimony Trioxide | 11.2% |
| Toluene diisocyanate homopolymer | 6.5% |
| (in Benzyl Benzoate) | |

The material of the seventh layer 114 can be selected or formulated to provide an additional protective layer. For example, the seventh (protective) layer 114 may be formed of, comprise or include polyvinyl chloride, a polyvinyl chloride material or a polyvinyl chloride film. The material of the seventh layer 114 can also be selected for resistance to abrasion, resistance to moisture or both.

The seventh layer 114 can also include pigment, or otherwise be colored. For example, the seventh layer 114 can include white, gray, green or brown pigments, or a combination of such colors. Depending on application, the seventh layer 114 can have a weight of about 4 ounces per square yard, or about 130 to about 140 GSM, or in a range of about 50 to 300 GSM, or more or less.

The textile coating 100 can also be flame or fire resistant. For example, one or more or all of the individual layers of the textile coating 100 may be formed of a flame or fire resistant material, or include one or more flame or fire retardant materials. In some instances, the protective materials of the first layer 102 and the seventh layer 114 can also provide flame resistance to the textile coating 100.

The textile coating 100 can have a total weight of about 16 to 18 ounces per square yard, or about 540 GSM or less to about 610 GSM or more. For example, the textile coating 100 may have a total weight of about 17 ounces per square yard, or about 570 to about 580 GSM. The textile coating 100 may also have a total weight of less than 17 ounces per square yard, or less than about 547 GSM. An approximate distribution of weight in the textile coating 100 is shown in Table 3.

The textile coating 100 can be provided with materials that are resistant to the growth of mold, mildew and fungus. The textile coating 100 can also be capable of withstanding extreme temperatures. For example, each of the seven layers of the textile coating 100 may be able to withstand temperatures down to −60 degrees Fahrenheit, or less than −50 C.

TABLE 3
Textile coating 100 (approximate composition)

| | | % of total weight | oz/yd² |
|---|---|---|---|
| Layer | Layer type | (approximate) | (approximate) |
| 1 | Protective layer | 29.4% | 5 |
| 2 | Adhesive layer | 4.7% | 0.8 |
| 3 | Strength layer | 21.2% | 3.6 |
| 4 | Adhesive layer | 4.7% | 0.8 |
| 5 | Chemical resistance layer | 11.8% | 2 |
| 6 | Adhesive layer | 4.7% | 0.8 |
| 7 | Protective layer | 23.5% | 4 |
| TOTAL | | | 17 |

The textile coating 100 can have limited stretching properties. Sewing the fabric layer 101 with the textile coating 100 applied may, in some conditions, limit the effectiveness of the textile coating 100 to protect against the penetration of permeable gases and fluids. Instead, or in combination, the textile coating 100 can be welded together. In some instances, to prevent damage to or delamination of the different materials of the textile coating 100, the textile coating 100 may be welded using a relatively low temperature welding process.

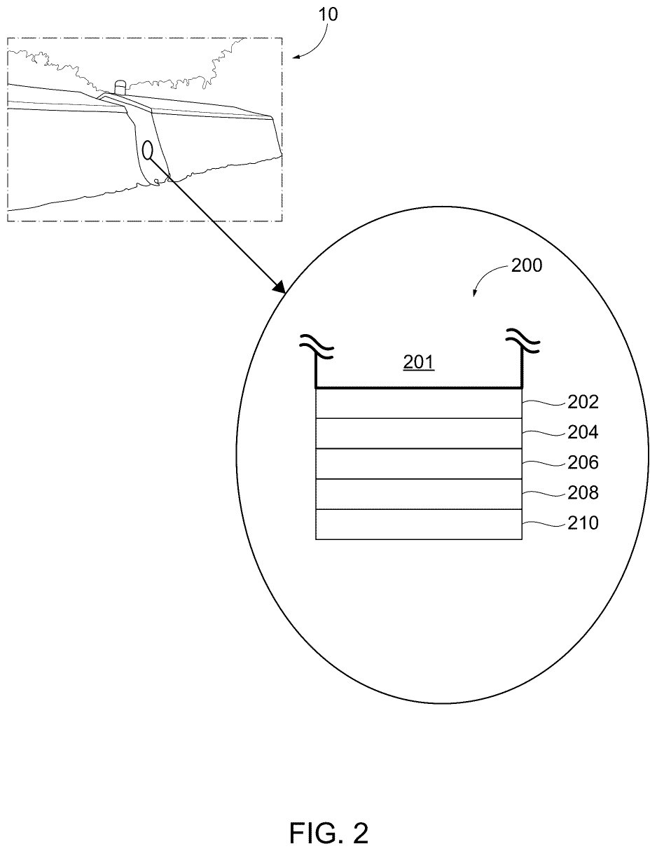

FIG. 2 is a schematic diagram of a structure 10 with a protective fabric liner system 200 disposed on the interior surface of a textile or fabric material 201 of a structure 10, as described herein. Referring to FIG. 2, a suitable liner system 200 can include five layers. The liner system 200 can include one or more of a first layer 202, a second layer 204, a third layer 206, a fourth layer 208, and a fifth layer 210.

The first layer 202 can be formed of or include materials selected to provide a protective layer, for example materials similar to those of the protective (first) layer 102 or the protective (seventh) layer 114, as described above for FIG. 1. For example, the first layer 202 may be formed from or comprise a polyvinyl chloride (PVC) film, or other PVC material. The material of the first layer 202 can also be resistant to abrasion or provide resistance to moisture, or both. The first layer 202 can be colored with white, gray, or variously colored pigments, or a combination of different colors. Depending on application, the first layer 202 can have a weight of about 3 ounces per square yard, or about 100 to about 105 GSM, or in a range of about 50 to 200 GSM, or more or less.

The second layer 204 can be formed from or include an adhesive, for example a chemical adhesive similar to those of the second (adhesive) layer 104 or the fourth (adhesive) layer 108, or the sixth (adhesive) layer 112, as described in FIG. 1. The adhesive in the second layer 204 can be selected, formulated, specifically adapted or otherwise configured to bond with the first layer 202, for example via a chemical bonding process. The second layer (adhesive layer) 204 can also be configured to bond with the third layer 206; e.g., via a similar chemical process. Depending on the application, the second layer 204 can have a weight of about 0.75 ounces per square yard, or about 20 to about 30 GSM, or in a range of about 10 to 60 GSM, or more or less.

The third layer 206 can be configured to provide strength and structural stability to the protective fabric liner system 200. For example, the third (structural) layer 206 can be formed of or include materials selected to provide strength and stability, including materials similar to those of the third (structural) layer 106, as described above for FIG. 1. The third (structural) layer 206 can be formed of or include a polyester material, a polyester film, a polyester scrim, or a greige cloth. For example, the third layer 206 can be formed of a woven polyester fabric, or other woven fabric material. Depending on the desired strength, density, and other properties, the third layer 206 can have a density of approximately 14×14 (1000 D×1000 D), or approximately 9×9 (500 D×500 D), for example in a weft inserted warp knit configuration. Depending on the application, the third layer 206 may have a weight of about 3.6 ounces per square yard, or about 120 to about 125 GSM, or in a range of about 10-60 GSM, or more or less.

The fourth layer 208 can include or comprise an adhesive, for example an adhesive similar to that of the fourth (adhesive) layer 108, as described above for FIG. 1. The fourth layer 208 can be formed of or include a resin type adhesive. The adhesive in the fourth layer 208 can be selected to formulated to “attack” (react with) the material of the fifth layer 210, in order to create a bond. For example, the adhesive of the fourth layer 208 can be formulated to bond with the material of the fifth layer 210 via a chemical reaction with the material of the fifth layer 210. the adhesive in the fourth layer 208 can also permeate, partially permeate, migrate, or partially migrate the material of the fifth layer 210 to create a chemical or chemically activated bond from the reaction with the adhesive.

The adhesive of the fourth layer 208 can also bond with the material of the third (structural) layer 206. Typically, the adhesive in the fourth layer 208 can bond with the material of the third layer 206 via a chemical reaction. Depending on the selected type and concentration of adhesive material, fourth layer 208 can have a weight of about 0.75 ounces per square yard, or about 20 to about GSM, or in a range of about 10 to 60 GSM, or more or less.

The fifth layer 210 can be selected, formulated, specially adapted or otherwise configured to provide chemical resistance. In some applications, the fifth layer 210 can include or comprise a polyvinyl fluoride (PVF), a PVF material, or a PVF film. For example, the fifth (chemical resistant) layer 210 can be configured as a PVF film.

The material of the fifth layer 210 can be selected or formulated to prevent transmission of permeable chemical agents and biological warfare vectors. The material of the fifth layer 210 can also be selected to have a reduced or minimal impact on the environment, compared to other disfavored materials such as polytetrafluoroethylene (PTFE), and related compounds. Depending on the application, the fifth layer 210 may have a weight of about 2 ounces per square yard, or about 65 to 70 GSM, or in a range of about 30 to 150 GSM, or more of less.

The fifth layer 210 can also include pigment, or otherwise be colored. For example, the fifth layer 210 can include white, gray, green, or brown pigments, or a combination of such colors.

An approximate distribution of weight in the protective fabric liner system 200 is shown in Table 4.

TABLE 4
Protective fabric liner system 200 (approximate composition)

| | | % of total weight | oz/yd² |
|---|---|---|---|
| Layer | Layer type | (approximate) | (approximate) |
| 1 | Protective layer | 38.0% | 3 |
| 2 | Adhesive layer | 8.9% | 0.7 |
| 3 | Strength layer | 18.9% | 1.5 |
| 4 | Adhesive layer | 8.9% | 0.7 |
| 5 | Chemical resistance layer | 25.3% | 2 |
| TOTAL | | | 7.9 |

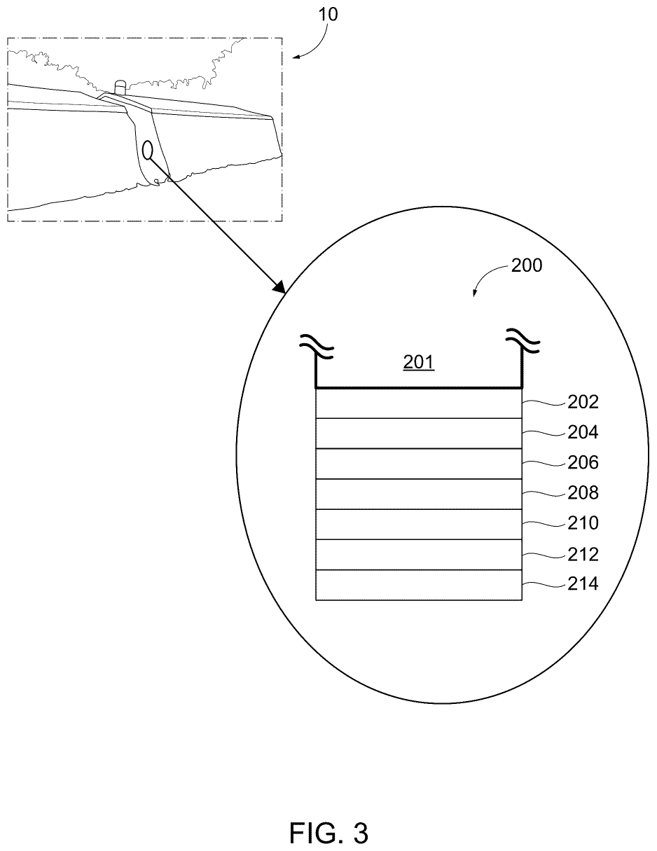

FIG. 3 is a schematic diagram illustrating an alternate layer configuration for the protective fabric liner system 200, as described herein. Referring to FIG. 3 the liner system 200 can include seven layers. For example, the liner system 200 can include one or more of a sixth layer 212 and a seventh layer 214, in addition to the first layer 202, the second layer 204, the third layer 206, the fourth layer 208, and the fifth layer 210, as described above for FIG. 2.

The sixth layer 212 can include or comprise an additional adhesive material. The adhesive of the sixth layer 212 similar to that of the second layer 204 or the fourth layer 208. For example, the sixth layer 212 can comprise or include a chemical adhesive that bonds with the surrounding (adjacent) layers through a chemical reaction, migration, and/or permeation of the layer. depending on the application, the sixth layer 212 can have a weight of about 0.75 ounces per square yard, or about 20 to about 30 GSM, or in a range of about 10 to 60 GSM.

The material of the seventh layer 214 can be selected or formulated to provide an additional protective layer. For example, the seventh (protective) layer 214 can be formed of, comprise, or include a polyvinyl chloride, a polyvinyl chloride material, or a polyvinyl chloride film. The material of the seventh layer 214 can also be selected for resistance to abrasion, moisture, or both.

The seventh layer 214 can also include pigment, or otherwise be colored. For example, the seventh layer 214 can include white, gray, brown, or green pigments, or a combination of such colors. Depending on the application, the seventh layer 214 can have a weight of about 3 ounces per square yard, or about 130 to about 140 GSM, or in a range of about 50 to 300 GSM, or more or less.

The protective fabric liner system 200 including seven layers can have a total weight of about 10.5 to 11.5 ounces per square yard, or about 350 GSM or less to about 390 GSM or more. For example, the protective fabric liner system 200 can have a total weight of about 11 ounces per square yard, or about 370 GSM to about 380 GSM. The protective fabric liner system 200 can also have a total weight of less than 11 ounces per square yard, or less than about 370 GSM. An approximate distribution of weight in the protective fabric liner system 200 is shown in Table 5.

The protective fabric liner system 200 can also be flame or fire resistant. For example, one or more or all of the individual layers of the liner system 200 can be flame resistant, or include flame retardant materials. In some instances, the protective materials of the first layer 202, the fifth layer 210, and/or the seventh layer 214 can also provide flame resistance to the liner system 200.

TABLE 5
Protective fabric liner system 200 (approximate composition)

| | | % of total weight | oz/yd² |
|---|---|---|---|
| Layer | Layer type | (approximate) | (approximate) |
| 1 | Protective layer | 25.9% | 3 |
| 2 | Adhesive layer | 6.0% | 0.7 |
| 3 | Strength layer | 13.0% | 1.5 |
| 4 | Adhesive layer | 6.0% | 0.7 |
| 5 | Chemical resistance layer | 17.2% | 2 |
| 6 | Adhesive layer | 6.0% | 0.7 |
| 7 | Protective layer | 25.9% | 3 |
| TOTAL | | | 11.6 |

The liner system 200 can be provided with materials that are be resistant to the growth of mold, mildew, and fungus. The liner system 200 can also be capable of withstanding extreme temperatures. For example, each of the five or seven layers of the liner system 200 can be able to withstand down to −60 degrees Fahrenheit, or less than −50 C.

The liner system 200 can have limited stretching properties. In some instances, the liner system 200 with seven layers can be welded together, sewn together, or a combination thereof. In some instances, to prevent damage to or delamination of the different materials of the liner system 200, the liner system 200 can be welded using a relatively lower temperature welding process.

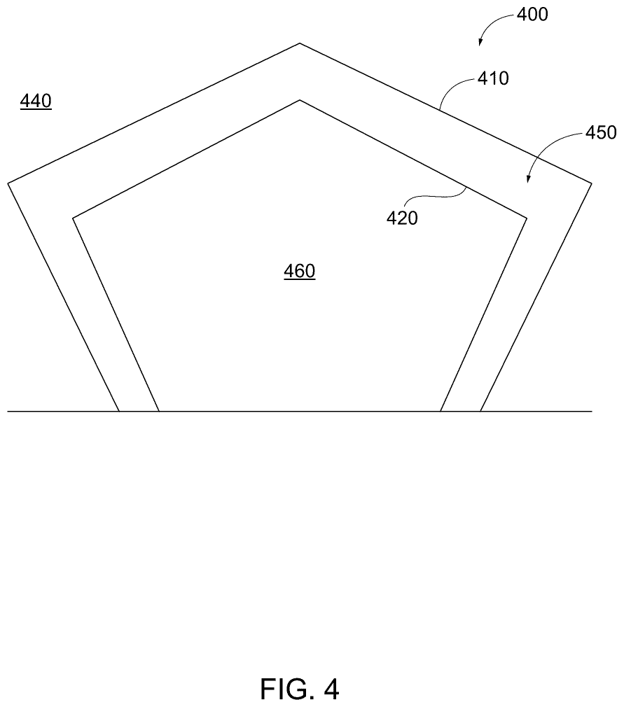

FIG. 4 is a front elevation view of a structure 400 with one or both of a protectively coated textile 100 and a coted fabric or textile 200, as described herein. Referring to FIG. 4, for example, the structure 400 can include an outer wall system 410 formed by applying a textile coating system 100 to a layer of textile or fabric material 101, as described above, and a protective fabric liner 420 formed from a coated fabric or textile system 200.

The outer wall system 410 and protective fabric liner 420 can each include up to five, seven or more layers of various protective, structural, and resistant materials bonded together with adhesives, as described herein, or fewer or more layers. For example, the outer wall system 410 can be formed by applying a protective coating 100 to a layer of textile or fabric material in order to create the outer barrier for the structure 400, in order to protection occupants from the exterior environment 440. A protective liner 420 can formed from a coated textile system 200, in order to create the inner surface or inner barrier defining the interior space 460 of the structure 400.

The outer wall system 410 and protective liner 420 can be used for portable and permanent structures, including dining or sleeping facilities, warehouses, maintenance facilities, command centers, classrooms, medical facilities, offices, and training and fitness facilities. Depending on application, the outer wall system 410 may include more individual layers than the protective liner 420, and have a greater total weight. The relative position and orientation of the outer wall 410 and protective liner 420 can also be reversed.

In addition to the intrinsic protection provided by the outer wall system 410 and protective liner 420, the configuration of structure 400 can also be adapted to further reduce the risk of introducing contaminants from the exterior environment 440 into the interior 460. For example, the coated textile system 410 and the liner system 420 can be spaced apart to form an air gap 450, which can be pressurized (e.g., with a positive overpressure, as compared to the exterior environment 440), in order to reduce or prevent inflow from holes or punctures formed in one or both of the outer wall system 410 and the protective liner 420.

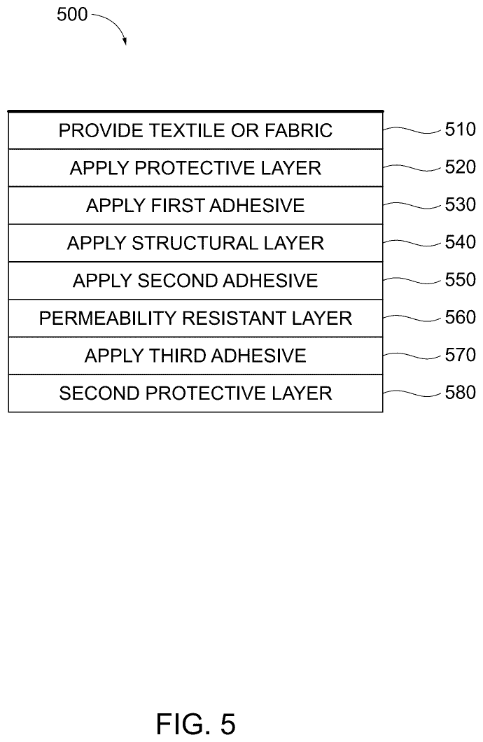

FIG. 5 is a block diagram illustrating a method 500 for applying a protective coating to a layer of textile or fabric. As shown in FIG. 5, method 500 can include one or more processes including, but not limited to:
Providing a layer of textile or fabric material (step 510);
Applying a layer of protective material; e.g., on, over or onto the textile or fabric material (step 520);
Applying a layer of adhesive material; e.g., on, over or onto the protective material (step 530);
Applying a layer of structural material; e.g., on, over or onto the adhesive material (step 540);
Applying a second layer of adhesive material; e.g., on, over or onto the structural material (step 550);
Applying a layer of permeability resistant material; e.g., on, over or onto the second layer of adhesive material (step 560);
Applying a third layer of adhesive material; e.g., on, over or onto the permeability resistant material (step 570); and
Applying a second layer of protective material; e.g., on, or over the third layer of adhesive material (step 580).

The first adhesive can be at least partially disposed between the structural and protective layers, when the protective material is applied, in order to bond them together as described above. Similarly, the second adhesive can be at least partially disposed between the structural layer and the permeability resistant layer, when the permeability resistant material is applied, so that the second adhesive chemically reacts with the permeability resistant material for form a chemical bond.

The third adhesive can be formulated to chemically react with the permeability resistant material, in order to form a chemical bond with the second protective layer. In these applications, the first, second and third adhesives can at least partially permeate the adjacent layers of the coated fabric or textile, in order to bond them together. An additional adhesive can also be provided when applying the first protective layer to the textile or fabric (step 510), for example to bond them together using any of the adhesive materials described above.

One or more of the first, second and third adhesives can be formed from or include a chemical adhesive material configured to react chemically with one or more adjacent layers of the textile coating, in order to form a chemical bond between them.

The protective layers can be formed from polyvinyl chloride, or include a polyvinyl chloride material or a polyvinyl chloride film. The structural layer be formed from a polyester material, or include a polyester film or a polyester scrim. The permeability resistant layer can be formed from polyvinyl fluoride, or include a polyvinyl fluoride material or polyvinyl film.

The coated textile or fabric can be resistant to corrosion, and fire or flame resistant, or a combination thereof. The coated textile or fabric can also be resistant to the transmission of permeable gases or fluids, including chemical agents, biological vectors, environmental contaminants, and other hazards.

In lighter applications, the coated textile or fabric can have a total weight of about 7.8 ounces per square yard, or about 260-270 grams per square meter, about 230-300 grams per square meter, or about 200-350 grams per square meter. In heavier applications, the coated textile or fabric can have a total weight of about 17 ounces per square yard, or about 570-580 grams per square meter, about 550-600 grams per square meter, or about 500-700 grams per square meter.

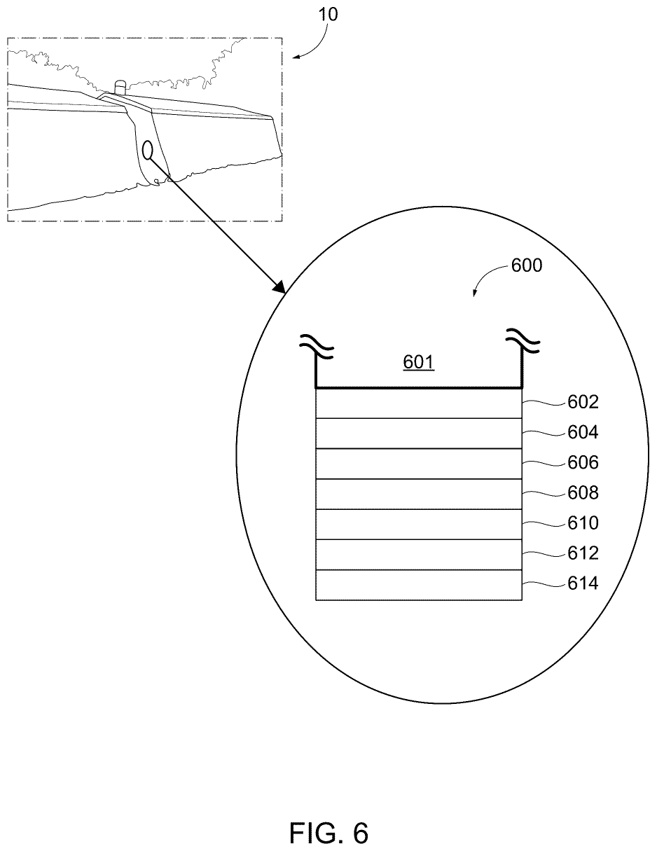

FIG. 6 is a schematic diagram of a structure 10 with a protective fabric liner system 600 disposed on the interior surface of a textile or fabric material 601 of a structure 10, as described herein. Referring to FIG. 6, a suitable liner system 600 can include seven layers. The liner system 600 can include one or more of a first layer 602, a second layer 604, a third layer 606, a fourth layer 608, a fifth layer 610, a sixth layer 612, and a seventh layer 614.

The first layer 602 can be a protective layer. In some applications, for example, the first layer (protective layer) 602 is formed of or includes polyvinyl chloride (PVC), or a PVC material or PVC film. Depending on formulation the first layer 102 can provide resistance to weather. The first layer 602 can also provide resistance to abrasion and tears. The first layer 602 can also be resistant to chemicals.

Depending on application, the first (protective) layer 602 may can be approximately 4-5 mm thick. The first layer 602 can be colored or pigmented to modulate absorption of solar energy (e.g., to increase reflectance and decrease heat capture, or to decrease reflectance and increase heat capture), or to provide camouflaging. For example, the first layer 602 may be provided with white, tan, green, brown, black, or other pigments, or a combination thereof. Depending on application, the first layer 602 can also have a weight of about 5 ounces per square yard, or about 165-175 grams per square meter (GSM), or in a range or about 50 to 350 GSM, or more or less.

The second layer 604 can be formed from or comprise an adhesive, for example a chemical adhesive or a resin adhesive. The adhesive in the second layer 604 can be selected, formulated, specially adapted or otherwise configured to bond with the first layer 602, for example via a chemical bonding process. The second layer (adhesive layer) 604 can also be configured to bond with the third layer 606; e.g., via a similar chemical process. The adhesive in the second layer 604 can be selected or formulated to “attack” (react with or chemically etch) the material of the third layer 606, in order to create a bond. For example, the adhesive of the second layer 604 can be formulated to bond with the third layer 606 via a chemical reaction with the material of the third layer 606. The adhesive in the second layer 604 can also permeate, partially permeate, migrate, or partially migrate the material of the third layer 606 to create a chemical or chemically activated bond from the reaction with the adhesive.

The adhesive of the second layer 604 can include a plasticizer, a resin, a FR, and an adhesion promoter. The adhesive can also include a mildewcide. In an example, the adhesive of the second layer 604 can include approximately 42% of resin, approximately 36% of plasticizer, approximately 13.6% of FR, approximately 6.6% of adhesion promoter, and approximately 2% of mildewcide. In an example, the adhesive of the second layer 604 can include the components in Table 6.

TABLE 6
Second layer 604 (approximate composition)

| | Percent |
|---|---|
| Component | (approximate) |
| DUP (diundecyl phthalate) | 35.7% |
| 5% 4-Isothazolin-3-one, 2-octyl | 1.9% |
| (in dioctyl terephthalate/DOTP) | |
| T75M (PVC Resin) | 37.8% |
| Vestolit 137 (PVC Resin) | 4.2% |
| Alumina Trihydrate | 5.3% |
| Antimony Trioxide | 8.4% |
| Toluene diisocyanate homopolymer | 6.7% |
| (in Benzyl Benzoate) | |

Depending on application, the second layer 604 can have a weight of about 0.8 ounces per square yard, or about 20 to about 30 GSM, or in a range of about 10 to 60 GSM, or more or less.

The third layer 606 can be selected, formulated, specially adapted or otherwise configured to provide chemical resistance. In some applications, the third layer 606 can include or comprise polyvinyl fluoride (PVF), or a PVF material or PVF film. For example, the third (chemically resistant) layer 606 can be configured as a PVF film.

The material of the third layer 606 can be selected or formulated to prevent transmission of permeable chemical agents and biological warfare vectors. The material of the third layer 606 can also be selected to have a reduced or minimal impact on the environment, compared to other disfavored materials such as polytetrafluoroethylen (PTFE), and related compounds. Depending on application, the third layer 606 may have a weight of about 2 ounces per square yard, or about 65 to about 70 GSM, or in a range of about 30 to 150 GSM, or more or less.

The fourth layer 608 can include or comprise an adhesive, for example a resin type adhesive. The adhesive in the fourth layer 608 can be substantially similar to the adhesive of the second layer 604. For example, the adhesive of the fourth layer 608 can be formulated to bond with the third layer 606 via a chemical reaction with the material of the fifth layer 606. The adhesive in fourth layer 608 can also bond with the material of the fifth (structural) layer 610. Typically, the adhesive in the fourth layer 608 can bond with the material of the fifth layer 610 via a chemical reaction. Depending on the selected type and concentration of adhesive material, the fourth layer 608 can have a weight of about 0.8 ounces per square yard, or about 20 to about 30 GSM, or in a range of about 10 to 60 GSM, or more or less.

The fifth layer 610 can be configured to provide strength and structural stability to the protective fabric liner system 600. Depending on application, the third layer (or stability layer) 606 can be formed of or include a greige cloth, a polyester material, a polyester film, or a polyester scrim. For example, the fifth layer 610 can be formed of a woven polyester fabric, or other woven fabric material. Depending on desired strength, density and other properties, the fifth layer 610 can have a thread count or fiber density of approximately 14×14 (1000 D×1000 D), or approximately 9×9 (500 D×500 D), for example in a weft inserted warp knit configuration. Depending on application, the fifth layer 610 can have a weight of about 3.6 ounces per square yard, or about 120 to about 125 GSM, or in a range of about 10-60 GSM, or more or less.

The sixth layer 612 can be formed from or comprise an adhesive, for example a chemical adhesive or a resin adhesive. The adhesive in the sixth layer 612 can be selected, formulated, specially adapted or otherwise configured to bond with the seventh layer (EMI layer) 614, for example via a chemical bonding process. The sixth layer 612 can also be configured to bond with the fifth layer 610; e.g., via a similar chemical process. The adhesive in the sixth layer 612 can be selected or formulated to “attack” (react with or chemically etch) the material of the seventh layer 614, in order to create a bond. For example, the adhesive of the sixth layer 612 can be formulated to bond with the fifth layer 610 via a chemical reaction with the material of the fifth layer 610. The adhesive in the sixth layer 612 can also permeate, partially permeate, migrate, partially migrate, etch, or partially etch the material of the seventh layer 614 to create a chemical or chemically activated bond from the reaction with the adhesive.

The adhesive of the sixth layer 612 can include a plasticizer, a resin, a FR, and an adhesion promoter. The adhesive can also include a pigment. The pigment can modulate absorption of solar energy (e.g., to increase reflectance and decrease heat capture, or to decrease reflectance and increase heat capture), or to provide camouflaging. For example, the pigment of the sixth layer can be white, tan, green, brown, black, or other pigments, or a combination thereof. In an example, the adhesive of the sixth layer 612 can include approximately 44.8% of resin, approximately 39.6% of plasticizer, approximately 11.5% of FR, approximately 2.1% of adhesion promoter, and approximately 2.1% of pigment. In an example, the adhesive of the sixth layer 612 can include the components in Table 7.

TABLE 7
Sixth layer 612 approximate composition

| | Percent |
|---|---|
| Component | (approximate) |
| DINP (diisononyl phthalate) | 16.7% |
| Santicizer 154 | 22.9% |
| Vestolit 137 (PVC Resin) | 8.3% |
| Vestolit P 139 (PVC Resin) | 36.5% |
| Antimony Trioxide | 11.5% |
| Cymel 303 | 2.1% |
| Lamp Black (in dioctyl terephthalate/DOTP) | 2.1% |

Depending on application, the sixth layer 612 can have a weight of about 0.8 ounces per square yard, or about 20 to about 30 GSM, or in a range of about 10 to 60 GSM, or more or less.

The seventh layer 614 can be configured to prevent electro-magnetic interference through the protective fabric liner system 600. The seventh layer 614 can act as a Faraday cage to block electromagnetic fields. Depending on application, the seventh layer (or EMI layer) 614 can be formed of or include a woven fabric. The woven fabric can include metalized fibers woven into the fabric. The metalized fibers can include copper, zinc, silver, nickel, tin, or a combination thereof. In an example, seventh layer 614 can include a woven fabric with a metalized spray on coating. The metalized spray on coating may include a copper sulfate and zinc. In an example, the seventh layer 614 can have a surface resistance of about 0.02 ohms. Depending on application, the seventh layer 614 can have a weight of about 2.3 ounces per square yard, or about 75 to about 80 GSM, or in a range of about 50-105 GSM, or more or less.

The protective fabric liner system 600can also be flame or fire resistant. For example, one or more or all of the individual layers of the protective fabric liner system 600may be formed of a flame or fire resistant material, or include one or more flame or fire retardant materials. In some instances, the protective materials of the first layer 602 and the seventh layer 614 can also provide flame resistance to the protective fabric liner system 600.

The protective fabric liner system 600 can have a total weight of about 15 to 16 ounces per square yard, such as 15.3 ounces per square yard, or about 500 GSM or less to about 550 GSM or more. For example, the protective fabric liner system 600 may have a total weight of about 15 ounces per square yard, or about 505 to about 515 GSM. The protective fabric liner system 600 may also have a total weight of less than 17 ounces per square yard, or less than about 547 GSM.

The protective fabric liner system 600 can be provided with materials that are resistant to the growth of mold, mildew and fungus. The protective fabric liner system 600 can also be capable of withstanding extreme temperatures. For example, each of the seven layers of the protective fabric liner system 600 may be able to withstand temperatures down to −60 degrees Fahrenheit, or less than −50 C.

The protective fabric liner system 600can have limited stretching properties. Sewing the fabric layer 101 with the protective fabric liner system 600 applied may, in some conditions, limit the effectiveness of the protective fabric liner system 600 to protect against the penetration of permeable gases and fluids and EMI. Instead, or in combination, the protective fabric liner system 600 can be welded together. In some instances, to prevent damage to or delamination of the different materials of the protective fabric liner system 600, the protective fabric liner system 600 may be welded using a relatively low temperature welding process.

The protective fabric liner system 600 can be added, or retrofitted, to existing materials. The protective fabric liner system 600 can provide EMI shielding with chemical resistance. Thus, existing infrastructures can be updated to add the protective fabric liner system 600 and therefore receive the protection capabilities.

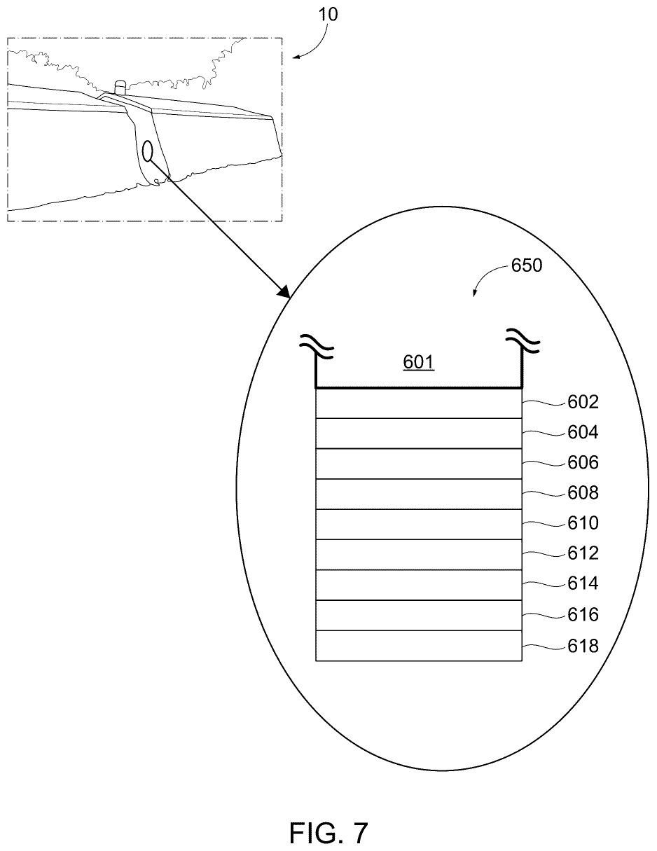

FIG. 7 is a schematic diagram of a structure 10 with a protective textile coating 750, as described herein. Referring to FIG. 7, a textile coating 650 can include multiple layers. For example, the textile coating 650 may include up to seven or more layers disposed on the inner side of a textile or fabric layer 601, in order to form a coated textile system. The coating layers can include the first layer first layer 602, the second layer 604, the third layer 606, the fourth layer 608, the fifth layer 610, the sixth layer 612, and the seventh layer 614, as described with respect to FIG. 6. The textile coating 650 can also include an eighth layer 616 and a ninth layer 618.

The eighth layer 616 can include or comprise an adhesive, for example an adhesive similar to that of the sixth (adhesive) layer 612, as described above for FIG. 6. For example, the adhesive of the eighth layer 616 can be formulated to bond with the seventh layer 614 via a chemical reaction with the material of the seventh layer 618. The adhesive in eighth layer 616 can also bond with the material of the ninth (protective) layer 618. Typically, the adhesive in the eighth layer 616 can bond with the material of the ninth layer 618 via a chemical reaction. Depending on the selected type and concentration of adhesive material, the eighth layer 616 can have a weight of about 0.8 ounces per square yard, or about 20 to about 30 GSM, or in a range of about 10 to 60 GSM, or more or less.

The ninth layer 618 can be a protective layer. In some applications, for example, the ninth layer (protective layer) 618 is formed of or includes polyvinyl chloride (PVC), or a PVC material or PVC film. Depending on formulation the ninth layer 618 can provide resistance to weather. The ninth layer 618 can also provide resistance to abrasion and tears. The ninth layer 618 can also be resistant to chemicals.

Depending on application, the ninth (protective) layer 618 may can be approximately 4-5 mm thick. The ninth layer 618 can be colored or pigmented to modulate absorption of solar energy (e.g., to increase reflectance and decrease heat capture, or to decrease reflectance and increase heat capture), or to provide camouflaging. For example, the ninth layer 618 may be provided with white, tan, green, brown, black, or other pigments, or a combination thereof. Depending on application, the ninth layer 618 can also have a weight of about 4 to 5 ounces per square yard, or about 130-175 grams per square meter (GSM), or in a range or about 50 to 350 GSM, or more or less.

The textile coating 650 can also be flame or fire resistant. For example, one or more or all of the individual layers of the textile coating 650 may be formed of a flame or fire resistant material, or include one or more flame or fire retardant materials. In some instances, the protective materials of the first layer 602 and the ninth layer 618 can also provide flame resistance to the textile coating 650.

The textile coating 650 can have a total weight of about 19.5 to 20.5 ounces per square yard, or about 660 GSM or less to about 700 GSM or more. For example, the textile coating 650 may have a total weight of about 20.1 ounces per square yard, or about 675 to about 685 GSM. The textile coating 650 may also have a total weight of less than 21 ounces per square yard, or less than about 712 GSM.

The textile coating 650 can be provided with materials that are resistant to the growth of mold, mildew and fungus. The textile coating 650 can also be capable of withstanding extreme temperatures. For example, each of the nine layers of the textile coating 650 may be able to withstand temperatures down to −60 degrees Fahrenheit, or less than −50 C.

The textile coating 650 can have limited stretching properties. Sewing the fabric layer 601 with the textile coating 650 applied may, in some conditions, limit the effectiveness of the textile coating 650 to protect against the penetration of permeable gases and fluids or EMI. Instead, or in combination, the textile coating 650 can be welded together. In some instances, to prevent damage to or delamination of the different materials of the textile coating 650, the textile coating 650 may be welded using a relatively low temperature welding process.

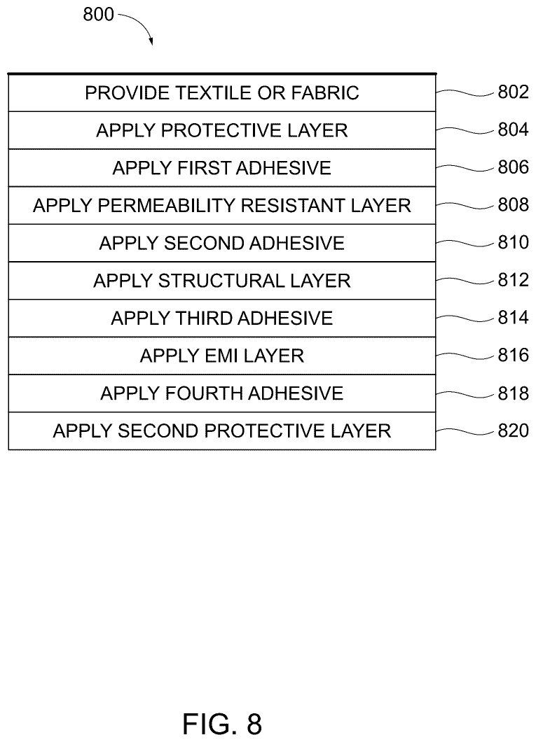

FIG. 8 is a block diagram of a method 800 for applying a protective coating to a layer of textile or fabric. As shown in FIG. 8, method 800 can include one or more processes including, but not limited to:
Providing a layer of textile or fabric material (step 802);
Applying a layer of protective material; e.g., on, over or onto the textile or fabric material (step 804);
Applying a layer of adhesive material; e.g., on, over or onto the protective material (step 806);
Applying a layer of permeability resistant material; e.g., on, over or onto the adhesive material (step 808);
Applying a second layer of adhesive material; e.g., on, over or onto the permeability resistant material (step 810);
Applying a layer of structural material; e.g., on, over or onto the second layer of adhesive material (step 812);
Applying a third layer of adhesive material; e.g., on, over or onto the structural material (step 814);
Applying an EMI resistant material; e.g., on, over or onto the third layer of adhesive material (step 816);
Applying a fourth layer of adhesive material; e.g., on, over or onto the EMI material (step 814); and
Applying a second layer of protective material; e.g., on, or over the fourth layer of adhesive material (step 820).

The first adhesive can be at least partially disposed between the protective and permeability resistant layers, when the permeability resistant material is applied, so that the adhesive chemically reacts with the permeability resistant material to form a chemical bond. Similarly, the second adhesive can be at least partially disposed between the permeability resistant layer and the structural layer, when the structural material is applied, in order to bond them together as described above. The first and second adhesives can be formulated to chemically react with the permeability resistant material, in order to form a chemical bond with the protective layer and the structural layer. In these applications, the first and second adhesives can at least partially permeate the adjacent layers of the coated fabric or textile, in order to bond them together.

The third adhesive can be at least partially disposed between the structural and EMI resistant layers, when the EMI material is applied, so that the adhesive chemically reacts with the EMI material to form a chemical bond. Similarly, the fourth adhesive can be at least partially disposed between the EMI layer and the protective layer, when the protective material is applied, in order to bond them together as described above. The third and fourth adhesives can be formulated to chemically react with the EMI material, in order to form a chemical bond with the structural layer and the protective layer. In these applications, the third and fourth adhesives can at least partially permeate the adjacent layers of the coated fabric or textile, in order to bond them together.

The protective layers can be formed from polyvinyl chloride, or include a polyvinyl chloride material or a polyvinyl chloride film. The structural layer be formed from a polyester material, or include a polyester film or a polyester scrim. The permeability resistant layer can be formed from polyvinyl fluoride, or include a polyvinyl fluoride material or polyvinyl film. The EMI layer can be formed from material woven with metalized fibers or a spray on EMI coating.

The coated textile or fabric can be resistant to corrosion, and fire or flame resistant, or a combination thereof. The coated textile or fabric can also be resistant to the transmission of permeable gases or fluids, including chemical agents, biological vectors, environmental contaminants, and other hazards. The coated textile or fabric can be resistant to EMI.

In lighter applications, the coated textile or fabric can have a total weight of about 15 ounces per square yard, or about 505-515 grams per square meter, about 475-545 grams per square meter, or about 445-575 grams per square meter. In heavier applications, the coated textile or fabric can have a total weight of about 20 ounces per square yard, or about 675-685 grams per square meter, about 555-705 grams per square meter, or about 480-880 grams per square meter.

In this description, specific details are set forth in order to provide an understanding and explanation of various examples, applications and embodiments of the present subject matter. It will be evident to those skilled in the art that these and other examples and embodiments of the present subject matter can be practiced without all the specific details described here, and that changes can be made and equivalents can be substituted in order to adapt these teachings to different problems, products and applications, and the scope of this invention is not limited except as set forth in the claims.

### Development of Bond Barrier in Protective Textiles

This disclosure was approached to explore solutions for chemical and biological protection that could enhance safety. Responding to this need, these techniques were conceptualized and developed. The claimed products emerged from a dedicated research and development process focused on creating robust fabric technology capable of withstanding the rigors of chemical and biological threats.

The initial formulation combined expertise in PVC lamination on polyester fabrics with groundbreaking advancements in layering technology. This process incorporated a fluoropolymer layer, chosen for its chemical resistance properties. To achieve strong inter-layer bonding, the layer was chemically etched to enable adhesion with a proprietary coating formulation. This custom coating facilitated the cohesive bonding of fluoropolymer, PVC and polyester layers.

The structure features a seven-layer configuration. The fluoropolymer layer is sandwiched between PVC and polyester cloth, with layers securing each component. The design was completed with additional specialized coating and PVC coatings, for encapsulation of the fluoropolymer. This multi-layered structure provided the chemical and biological resilience of a fluoropolymer in a versatile format suitable for welding-thus allowing the barrier to be processed similarly to traditional PVC-laminated products, making it ideal for real-world and military applications.

Over time, iterative modifications were made, focusing on improving the coating formulations to improve product integrity and longevity. These enhancements were integral to maintaining status as a leading solution in military-grade protective textiles.

### The Transition to PVF

The use of fluoropolymer materials can be subject to production process and specific use conditions. Some fluoropolymers can include per- and polyfluoroalkyl substances, prompting the development of a new products in which fluoropolymer is replaced with other (e.g., transparent, thermoplastic) materials such as polyvinylfluoride (PVF), an alternative which aligns with evolving environmental and health standards.

This represents a leap forward in material science. These PVF-based formulations, including updated coating formulations, provide a naturally robust bond between PVF and PVC layers. These coatings not only enhance layer cohesion but also support a wider range of applications. Another advantage of PVF layers is expanded production width, comparable to that of the PVC layer. These improvements allows products to be manufactured in wider rolls, reducing the need for seams, which can be a common source of vulnerability in other, traditional protective fabrics.

These broader capacities also simplify the fabrication processes, minimizing the likelihood of breaches, and enhancing overall durability. The resulting products deliver safer, more effective solutions for environmental protection and chemical and biological defense, while meeting contemporary environmental standards.

These commitments are made to innovation in protective textiles, offering solutions that continue to evolve alongside industry demands, marking a significant milestone, adapting to product demands and regulatory changes without compromising on performance. Through advanced coating chemistry and a focus on product scalability, newer standards in protective textiles, reinforcing the position as trusted products in these sectors and beyond.

TABLE 8
Bond Barrier

| Layer | Component | % of Construction | oz/yd² |
|---|---|---|---|
| 1 | PVC Film 1 | 29.4% | 5 |
| 2 | Coating 1 | 4.7% | 0.8 |
| 3 | Greige Cloth | 21.2% | 3.6 |
| 4 | Coating 1 | 4.7% | 0.8 |
| 5 | PVF Film | 11.8% | 2 |
| 6 | Coating 2 | 4.7% | 0.8 |
| 7 | PVC Film 1 | 23.5% | 4 |
| | Total | 100% | 17 |

TABLE 9
Bond Liner (non-encapsulated)

| Layer | Component | % of Construction | oz/yd² |
|---|---|---|---|
| 1 | PVC Film 1 | 38.0% | 3 |
| 2 | Coating 1 | 8.9% | 0.7 |
| 3 | Greige Cloth | 18.9% | 1.5 |
| 4 | Coating 1 | 8.9% | 0.7 |
| 5 | PVF Film | 25.3% | 2 |
| | Total | 100% | 7.9 |

TABLE 10
Bond Barrier (encapsulated)

| Layer | Component | % of Construction | oz/yd² |
|---|---|---|---|
| 1 | PVC Film 1 | 25.9% | 3 |
| 2 | Coating 1 | 6.0% | 0.7 |
| 3 | Greige Cloth | 13% | 1.5 |
| 4 | Coating 1 | 6.0% | 0.7 |
| 5 | PVF Film | 17.2% | 2 |
| 6 | Coating 2 | 6.0% | 0.7 |
| 7 | PVC Film 1 | 25.9% | 3 |
| | Total | 100% | 11.6 |

### EXAMPLES

Protective textile coating systems can be provided, for example comprising an electro-magnetic interference (EMI) resistant or EMI blocking layer, a structural layer, and a first adhesive selected, adapted or otherwise configured to bond the EMI layer and the structural layer. The system can also include a permeability resistant layer and a second adhesive selected, adapted or otherwise configured to interact with and form a chemical bond between the structural layer and the permeability resistant layer.

The EMI resistant layer can be made from or comprise a woven material including metalized fibers; e.g., where the metalized fibers include at least one of copper, nickel, tin, zinc, silver, or a combination thereof. The EMI resistant layer can be adapted or configured for the protective textile coating systems to be resistant to radio frequency (RF) signals or electromagnetic interference (EMI), or both, or to block such signals or interference arising from either an inside or outside direction with respect to the coating system.

The structural layer can be made from or comprise a polyester material, a polyester film, or a polyester scrim. The permeability resistant layer can be made from or comprise polyvinyl fluoride or a polyvinyl fluoride material, a polyvinyl fluoride film, or a combination thereof. One or both of the first and second adhesive can be made from or comprise a chemical adhesive material selected, adapted or otherwise configured to interact with one or more adjacent layers of the protective textile coating system; e.g. to chemically with react with one of more such adjacent layers in order to form a chemical bond with or between the adjacent layer or layers.

The protective textile coating systems can be configured or adapted to be resistant to corrosion, flame or fire resistant, or a combination thereof. The system can be configured or adapted to be resistant to transmission of permeable gases or fluids, or both, independently or in combination.

The protective textile coating systems can have a total weight of about 15.3 ounces per square yard; e.g., with a mass of about 518-520 grams per square meter. The total weight can range from about 15 to 16 ounces per square yard; e.g., with a mass of about 500 to 550 grams per square meter, or from about 10 to 20 ounces per square yard; e.g., with a mass of about 300 to 700 grams per square meter.

The protective layer can be provided, applied, or disposed on or onto a layer of textile or fabric, or between a layer of textile or fabric and the EMI resistant layer. An additional adhesive can be selected, adapted or otherwise configured to bond the protective layer to the permeability resistant layer.

One or both of the first and second (or additional) adhesives can be made from or comprise a composition including one or more components as described in Table 1. The adhesives can be made from or comprise a composition including one or more components as described in Table 2, Table 6, or Table 7, or any combination of the components in Tables 1, 2, 6 and 7.

Coated textile and fabric systems, textiles and fabric products can be provided by applying the protective coating system to a textile or fabric layer. For example, such a coated textile system can comprise a layer of textile or fabric, a first protective layer, a permeability resistant layer, a structural layer and an electro-magnetic interference (EMI) resistant layer or EMI blocking layer.

A first adhesive can be selected, adapted or otherwise configured to bond the first protective layer and the permeability resistant layer. A second adhesive can be selected, adapted or otherwise configured to react with or interact with the permeability resistant layer; e.g. in order to form a chemical bond between the permeability resistant layer and the structural layer. A third adhesive can be selected, adapted or otherwise configured to bond the structural layer and the EMI resistant layer;

A second protective layer can also be provided; e.g., with a fourth adhesive selected, adapted or otherwise configured to bond the fourth protective layer and the EMI resistant layer. The EMI resistant layer can be made from or comprise a woven material including metalized fibers; e.g., where the metalized fibers include at least one of copper, nickel, tin, zinc, silver, or a combination thereof. The coated textile system can be adapted or configured to be block or be resistant to RF signals or electromagnetic interference (EMI), or a combination of RF signals and EMI, arising either from an inside or outside direction (or both).

One or both of the first protective layer and the second protective layer can be made from or comprise polyvinyl chloride or a polyvinyl chloride material, a polyvinyl chloride film, or a combination thereof. The structural layer can be made from or comprise a polyester material, a polyester film, or a polyester scrim, or a combination thereof. The permeability resistant layer can be made from or comprises polyvinyl fluoride or a polyvinyl fluoride material, a polyvinyl fluoride film, or a combination thereof. One or more of the first, second, third, and fourth adhesive can be made from or comprise a chemical adhesive material configured to react chemically or otherwise interact with one or more adjacent layers of the coated textile system, to order to form a chemical bond to or between one or more such adjacent layers.

The coated textile systems can be adapted or configured to be resistant to corrosion, flame or fire resistant, or a combination thereof. The coated textile system can be adapted or configured to be resistant to transmission of permeable gases or fluids, independently or in combination.

The coated textile systems can have a total weight of about 20.1 ounces per square yard; e.g., with a mass of about 675 to 685 grams per square meter. The total weight can range from about 18 to 22 ounces per square yard; e.g., about 600 to 750 grams per square meter, or from about 15 to 25 ounces per square yard; e.g., about 500 to 850 grams per square meter.

The first protective layer can be disposed between the layer of textile or fabric and the permeability resistant layer. An additional adhesive can be selected, adapted or otherwise configured to bond the first protective layer to the layer of textile or fabric.

One or more of the first, second, third, and fourth (or additional) adhesives can be made from or comprise a composition including one or more components as described in Table 1. The adhesives can be made from or comprise a composition including one or more components as described in Table 2, Table 6 or Table 7, or any combination of the components in Tables 1, 2, 6, and 7.

Methods for making a protective costing or coated fabric system can include providing, applying or disposing a protective layer on or onto a layer of textile or fabric, providing, applying or disposing a first adhesive on or onto the protective layer, and providing, applying or disposing a structural layer on or onto the protective layer; e.g., with the first adhesive at least partially disposed therebetween. The first adhesive layer can be selected, adapted or otherwise configured to bond the protective layer and the structural layer.

A second adhesive can be provided, applied or disposed on or onto the structural layer, and an electro-magnetic interference (EMI) resistant layer can be provided, applied or disposed on or onto the structural layer; e.g., with the second adhesive at least partially disposed therebetween. The second adhesive can be selected, adapted or otherwise configured to chemically react or otherwise interact with the electro-magnetic interference (EMI) resistant layer, in order to form a bond between the electro-magnetic interference (EMI) resistant layer and the structural layer.

An additional adhesive can be provided, applied or disposed on or onto the layer of textile or fabric; e.g., where the additional adhesive is selected, adapted or otherwise configured to bond the protective layer to the fabric or textile. A permeability resistant layer can be provided, applied or disposed on or between the protective layer and the structural layer.

A third adhesive can be provided, applied or disposed on or onto the EMI resistant layer, and a second protective layer can be provided, applied or disposed on or onto the EMI resistant layer; e.g., with the third adhesive at least partially disposed therebetween. The third adhesive can be selected, adapted or otherwise configured to bond the EMI resistant layer and the second protective layer. One or more of the first, second and third (or additional) adhesives can be made from or comprise a chemical adhesive material selected, adapted or configured to react chemically or otherwise interact with one or more adjacent layers of the textile coating; e.g., to form a chemical bond to or between one or more such adjacent layers.

One or both of the first and second protective layer can be made from or comprise polyvinyl chloride or a polyvinyl chloride material, a polyvinyl chloride film, or a combination thereof. The structural layer can be made from or comprise a polyester material, a polyester film, a polyester scrim, or a combination thereof.

By practicing these methods, the layer of fabric can be adapted or configured to be resistant to corrosion, fire or flame resistant, resistant to transmission electro-magnetic waves, or a combination thereof. The layer of textile or fabric can have a total weight of about 15.3 ounces per square yard; e.g., with a mass of about 515-520 grams per square meter, or about 20.1 ounces per square yard; e.g., with a mass of about 675-685 grams per square meter. The total weight can be about 15 to 16 ounces per square yard; e.g., with a mass of about 500 to 550 grams per square meter; or about 10 to 20 ounces per square yards; e.g., with a mass of about 340 to 680 grams per square meter.

One or more of the first and second (or additional) adhesives can be made from or comprise a composition including one or more components as described in Table 1. The adhesives can be made from or comprise a composition including one or more components as described in Table 2, Table 6, or Table 7, or any combination of components described in Tables 1, 2, 6 and 7.

In any of these examples, the various layers of the protective coating or coated textiles and fabrics or textiles systems, textiles and fabric products can be made of or comprise one or more of the corresponding materials in Tables A, B and C, or a combination thereof. A structure can be provided, comprising a textile coating system applied to a layer of textile or fabric to form wall system. For example, the coated textile or fabric can be configured as an outer wall system, with a second coated textile system configured as a protective liner, as described herein.

This description is made with respect to representative examples and embodiments. Changes can be made and equivalents can be substituted to adapt these teachings to other applications, problems and materials, as understood by a person of skill in the art. The scope of invention is not limited to the specific examples that are disclosed, except as expressly recited in the claims, and encompasses all the embodiments falling within the plain language thereof.

1. A textile coating system comprising:
an electro-magnetic interference (EMI) resistant layer;
a structural layer;
a first adhesive configured to bond the EMI layer and the structural layer;
a permeability resistant layer; and
a second adhesive configured to form a chemical bond between the structural layer and the permeability resistant layer.

2. The textile coating system of claim 1, wherein the EMI resistant layer comprises a woven material including metalized fibers copper, nickel, tin, zinc, silver, or a combination thereof and resistant to electro-magnetic interference.

3. (canceled)

4. (canceled)

5. The textile coating system of claim 1, wherein;
the structural layer comprises a polyester material, a polyester film, or a polyester scrim; or
the permeability resistant layer comprises polyvinyl fluoride, a polyvinyl fluoride material, or a polyvinyl fluoride film.

6. (canceled)

7. The textile coating system of claim 1, wherein one or both of the first and second adhesive is adapted to react chemically with adjacent layers of the textile coating system to form a chemical bond therebetween.

8. The textile coating system of claim 1, wherein the textile coating system is resistant to corrosion, flame or fire resistant, or a combination thereof, and further resistant to transmission of permeable gases and fluids.

9. (canceled)

10. The textile coating system of claim 1, wherein the textile coating system has a total weight of about 15 ounces per square yard, or a mass of 505-515 grams per square meter, or 500-550 grams per square meter.

11. The textile coating system of claim 1, further comprising a layer of textile or fabric with a protective layer disposed thereon, between the layer of textile or fabric and the permeability resistant layer, and further comprising an additional adhesive configured to bond the protective layer to the permeability resistant layer.

12. The textile coating system of claim 1, wherein one or both of the first and second adhesive comprises a composition comprising one or more components as described in any of Tables 1, 2, 6, or 7.

13-15. (canceled)

16. A coated textile system comprising:
a layer of textile or fabric;
a first protective layer;
a permeability resistant layer;
a first adhesive configured to bond the first protective layer and the permeability resistant layer;
a structural layer;
a second adhesive configured to react with the permeability resistant layer to form a chemical bond between the permeability resistant layer and the structural layer;
an electro-magnetic interference (EMI) resistant layer;
a third adhesive configured to bond the structural layer and the EMI resistant layer;
a second protective layer; and
a fourth adhesive configured to bond the protective layer and the EMI resistant layer.

17. The coated textile system of claim 16, wherein the EMI resistant layer comprises a woven material including metalized fibers copper, nickel, tin, zinc, silver, or a combination thereof and resistant to electro-magnetic interference.

18-19. (canceled)

20. The coated textile system of claim 16, wherein:
one or both of the first protective layer and the second protective layer comprises polyvinyl chloride, a polyvinyl chloride material, or a polyvinyl chloride film;
the structural layer comprises a polyester material, a polyester film, or a polyester scrim; or
the permeability resistant layer comprises polyvinyl fluoride, a polyvinyl fluoride material, or a polyvinyl fluoride film.

21-22. (canceled)

23. The coated textile system of claim 16, wherein one or more of the first, second, third, and fourth adhesive is adapted to react chemically with one or more adjacent layers of the coated textile system to form a chemical bond therebetween.

24. The coated textile system of claim 16, wherein the coated textile system is resistant to corrosion, flame or fire resistant, or a combination thereof and further resistant to transmission of permeable gases and fluids.

25. (canceled)

26. The coated textile system of claim 16, wherein the coated textile system has a total weight of about 20 ounces per square yard, or a mass of 675-685 grams per square meter, or 600-800 grams per square meter.

27. The coated textile system of claim 16, wherein the first protective layer is disposed between the layer of textile or fabric and the permeability resistant layer, and further comprising an additional adhesive configured to bond the first protective layer to the layer of textile or fabric.

28. The coated textile system of claim 16, wherein one or more of the first, second, third, and fourth adhesive comprises a composition comprising one or more components as described in any of Tables 1, 2, 6, or 7.

29-31. (canceled)

32. A method comprising:
applying a protective layer to a layer of textile or fabric;
applying a first adhesive to the protective layer;
applying a structural layer to the protective layer with the first adhesive at least partially disposed therebetween, wherein the first adhesive is configured to bond the protective layer and the structural layer;
applying a second adhesive to the structural layer;
applying an electro-magnetic interference (EMI) resistant layer to the structural layer with the second adhesive at least partially disposed therebetween, wherein the second adhesive is configured to chemically react with the EMI resistant layer to form a bond between the EMI resistant layer and the structural layer.

33. The method of claim 32, further comprising applying an additional adhesive to the layer of textile or fabric, wherein the additional adhesive is configured to bond the protective layer to the fabric or textile and further comprising applying a permeability resistant layer between the protective layer and the structural layer.

34. (canceled)

35. The method of claim 32, further comprising:
applying a third adhesive to the EMI resistant layer; and
applying a second protective layer to the EMI resistant layer, with the third adhesive at least partially disposed therebetween;
wherein the third adhesive is configured to bond the EMI resistant layer and the second protective layer.

36. The method of claim 35, wherein one or more of the first, second, and third adhesives is adapted to react chemically with one or more adjacent layers of the textile coating to form a chemical bond therebetween.

37. The method of claim 35, wherein one or both of the first and second protective layer comprises polyvinyl chloride or polyvinyl fluoride, a polyvinyl chloride or polyvinyl fluoride material, or a polyvinyl chloride or polyvinyl fluoride film or wherein the structural layer comprises a polyester material, a polyester film, or a polyester scrim.

38-45. (canceled)
